(19) United States
(12) Patent Application Publication
(10) Pub. No.: US 2008/0160686 A1
(43) Pub. Date: Jul. 3, 2008

(54) SEMICONDUCTOR DEVICE AND METHOD OF MANUFACTURING SAME

(75) Inventors: Ikuo NAKAMATSU, Kawasaki (JP); Makoto YASUDA, Kawasaki (JP); Toshiyuki TAKEWAKI, Kawasaki (JP); Yasutaka NAKASHIBA, Kawasaki (JP); Shinichi UCHIDA, Kawasaki (JP)

Correspondence Address: Young & Thompson, Second Floor, 745 S. 23rd Street, Arlington, VA, 22202, US

(73) Assignee: NEC ELECTRONICS CORPORATION, Kawasaki (JP)

(21) Appl. No.: 11/872,797

(22) Filed: Oct. 16, 2007

(30) Foreign Application Priority Data
Oct. 16, 2006 (JP) 2006-281475

(51) Int. Cl. H01L 21/8244; H01L 21/20; H01L 21/4763; H01L 21/8238

(52) U.S. Cl. 438/238; 438/381; 438/210; 438/622

(57) ABSTRACT

A semiconductor device includes a semiconductor substrate, a field effect transistor (FET), contact plugs, a resistive element (specific member) and interconnects. Contact plugs are connected to the FET. A resistive element is provided in the layer (lowermost layer of interconnect layer) that also includes the contact plug. The contact plug and the resistive element are formed of the same material. Portions of the upper surface of the resistive element are connected to the interconnects.

This application is based on Japanese patent application No. 2006-281,475, the content of which is incorporated hereinto by reference.

### BACKGROUND

1. Technical Field

The present invention relates to a semiconductor device and a method of manufacturing thereof.

2. Related Art

FIG. 7 is a cross-sectional view, showing a conventional semiconductor device. Now concerning a semiconductor device 100, a transistor 102 and a shallow trench isolation (STI) 103 are formed in a semiconductor substrate 101. A polysilicon resistor 104 is provided on the semiconductor substrate 101. A sheet resistance of the polysilicon resistor 104 is, for example, 450 Ω/sq. The polysilicon resistor 104 is connected to an interconnect (not shown) through an electroconducting plug 105. Further, a contact plug 106 is connected to the transistor 10

The polysilicon resistor 104, the electroconducting plug 105 and the contact plug 106 are formed to be disposed in the lowermost layer of an interconnect layers 107 provided in a form of a multiple-layered structure. A metallic resistor 108 is provided to form the uppermost layer of the interconnect layer 107. The metallic resistor 108 is composed of, for example, titanium nitride (TiN). In such case, the sheet resistance thereof is, for example, 20 Ω/sq. Such metallic resistor 108 is connected to an interconnect (not shown) by an electroconducting plug 109.

FIG. 8 is a perspective view, showing a polysilicon resistor 104 or a metallic resistor 108. In case of showing the former, a height h2 and a width w2 thereof are, for example, 0.1 μm and 1 μm, respectively. In case of showing the latter, a height h2 and a width w2 thereof are, for example, 0.01 μm and 0.3 μm, respectively.

The prior art literatures related to the present invention include Japanese Patent Laid-Open No. 2004-40,009 and Japanese Patent Laid-Open No. H10-65,101 (1998).

The present inventors have recognized as follows. When passive element such as the polysilicon resistor 104 or the metallic resistor 108 is provided in such manner, it is necessary to include additional process operations for forming the passive element. This results in increased number of the process operations for manufacturing the semiconductor devices.

### SUMMARY

According to one aspect of the present invention, there is provided a semiconductor device, comprising: a semiconductor substrate having a transistor formed therein; a contact plug, provided on the semiconductor substrate and connected to the transistor; a specific member constituting a passive element, the specific member being provided in a layer on the semiconductor substrate that also includes the contact plug, and being composed of a material that also composes the contact plug; and an interconnect connected to a portion of an upper surface of the specific member.

In such semiconductor device, the specific member that constitutes a passive element is provided in a layer that also includes the contact plug and is composed of the same material as that of the contact plug. Therefore, the specific member can be formed simultaneously with forming the contact plug. This allows obtaining the passive element without causing an increased number of manufacturing process operations.

According to another aspect of the present invention, there is provided a method of manufacturing a semiconductor device, comprising: forming a transistor in a semiconductor substrate; forming a contact plug on the semiconductor substrate so as to be connected to the transistor; forming a specific member constituting a passive element on the semiconductor substrate; and forming an interconnect so as to be connected to a portion of an upper surface of the specific member, wherein the contact plug is formed simultaneously with forming the specific member.

In such manufacturing process, the specific member, which constitutes the passive element, is formed simultaneously with forming the contact plug. This allows obtaining the passive element without causing an increased number of manufacturing process operations.

According to the present invention, the semiconductor device and the method of manufacturing thereof, which allows obtaining the passive element without causing an increased number of manufacturing process operations, are achieved.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view, showing first embodiment of a semiconductor device according to the present invention;

FIG. 2 is a perspective view, showing a portion of the semiconductor device of FIG. 1;

FIG. 3 is a cross-sectional view, showing second embodiment of a semiconductor device according to the present invention;

FIG. 4 is a perspective view, showing a portion of the semiconductor device of FIG. 2;

FIG. 5 is a perspective view, useful in describing a modified embodiment;

FIG. 6 is a perspective view, useful in describing another modified embodiment;

FIG. 7 is a cross-sectional view, showing a conventional semiconductor device;

FIG. 8 is a perspective view, showing a portion of the semiconductor device of FIG. 7;

FIG. 9 is a perspective view, useful in describing another modified embodiment; and

FIGS. 10A and 10B is a perspective view, useful in describing another modified embodiment.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferable exemplary implementations of semiconductor devices and methods for manufacturing semiconductor devices according to the present invention will be described in reference to the annexed figures. In all figures, identical numeral is assigned to an element commonly appeared in the description of the present invention in reference to the figures, and the detailed description thereof will not be repeated.

### First Embodiment

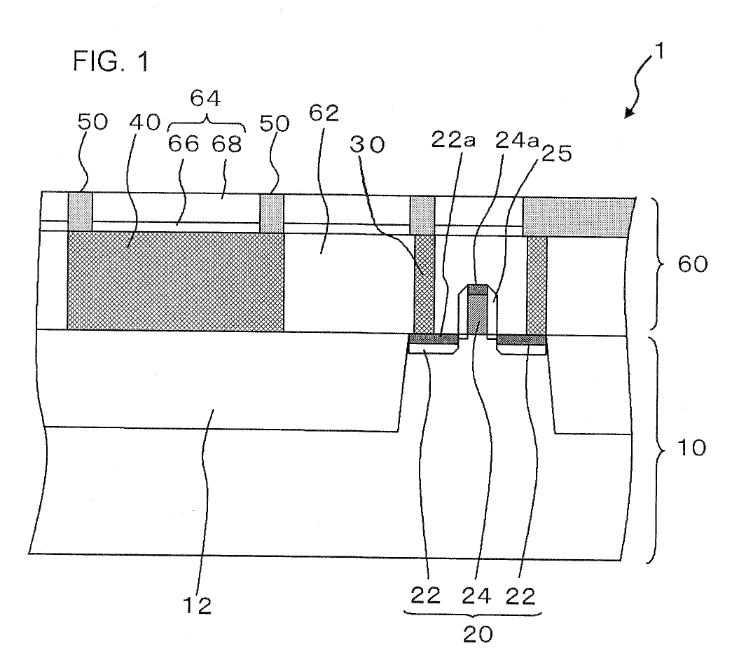

FIG. 1 is a cross-sectional view, showing first embodiment of a semiconductor device according to the present invention. A semiconductor device 1 includes a semiconductor substrate 10, a field effect transistor (FET) 20, contact plugs 30, a resistive element 40 (specific member) and interconnects 50. In the present embodiment, the semiconductor substrate 10 is a silicon substrate. A shallow trench isolation (STI) 12 serving as an element isolation region is formed in the semiconductor substrate 10. Further, an interconnect layer 60 is provided on the semiconductor substrate 10. The interconnect layer 60 includes a contact interconnect layer 62 and a first interconnect-interconnect layer 64. Further, the first interconnect-interconnect layer 64 includes an etch stop film 66 and a first interconnect-interlayer insulating layer 68.

A field effect transistor (FET) 20 is also formed in the semiconductor substrate 10. The field effect transistor 20 includes source-drain regions 22 formed in the semiconductor substrate 10 and a gate electrode 24 formed on the semiconductor substrate 10. Upper surface layers 22a of the source-drain regions 22 and an upper surface layer 24a of the gate electrode 24 are silicidized, respectively. Further, a side wall 25 is formed on the side surface of the gate electrode 24.

Contact plugs 30 are connected to the source-drain regions 22 of the FET 20. A resistive element 40 is provided in the layer (contact-interconnect layer 62) that also includes the contact plug 30. The resistive element 40 is provided on the STI 12 in the semiconductor substrate 10. The height of contact plug 30 is equivalent to the height of the resistive element 40. Further, the contact plug 30 and the resistive element 40 are formed of the same material. Such materials typically includes, for example, tungsten (W). In addition to above, layers of a barrier metal such as titanium nitride (TiN) may be provided on the side surfaces and on the lower surfaces of the contact plug 30 and the resistive element 40. When the resistive element 40 is composed of W and TiN, the sheet resistance is, for example, 2.1 Ω/sq.

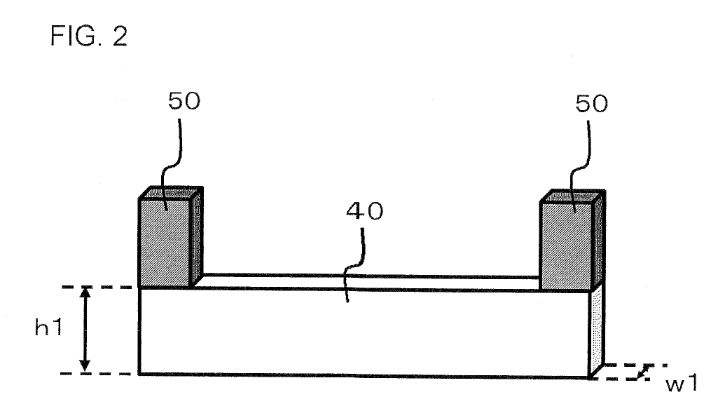

FIG. 2 is a perspective view, showing the resistive element 40 and the interconnects 50. As can be seen from this diagram, the resistive element 40 elongates along direction that is in parallel with the substrate surface of the semiconductor substrate 10 (transverse direction in the diagram). Accordingly, the shortest electric current path through the resistive element 40 is also in parallel with the substrate surface. Further, a surface having the largest area in the surfaces in the resistive element 40 is perpendicular to the substrate surface of the semiconductor substrate 10. Here, a height h1 of the resistive element 40 is, for example, about 0.3 μm. Further, the resistive element 40 has uniform width, and such width w1 is, for example, about 0.1 μm.

Portions of the upper surface of the resistive element 40 are connected to the interconnects 50. More specifically, the resistive element 40 is connected to the interconnect 50 at both ends in the elongation direction. The resistive element 40 is directly connected to the interconnects 50. In the present embodiment, the interconnect 50 is a copper interconnect.

Returning to FIG. 1, an example of a method of manufacturing the semiconductor device 1 will be described as an embodiment of a method of manufacturing the semiconductor device according to the present invention. First of all, the FET 20 is formed in the semiconductor substrate 10. Next, the contact plug 30 is formed on the semiconductor substrate 10 so as to be connected to the FET 20, and the resistive element 40 is formed on the semiconductor substrate 10. The contact plug 30 and the resistive element 40 are simultaneously formed. Thereafter, the interconnects 50 are formed so as to be connected to portions of the upper surface of the resistive element 40. In the present embodiment, the interconnect 50 is formed by a damascene process.

Advantageous effects of the present embodiment will be described. In the semiconductor device 1, the resistive element 40 is provided in a layer that also includes the contact plug 30 and is composed of the same material as that of the contact plug 30. Therefore, the resistive element 40 can be formed at the same time as forming the contact plug 30. More specifically, the resistive element 40 can be formed by only suitably designing a patterned mask for forming the contact plug 30. Actually, in the above described manufacturing process, the resistive element 40 is formed at the same time as forming the contact plug 30. This allows obtaining the resistive element 40 without causing an increased number of manufacturing process operations.

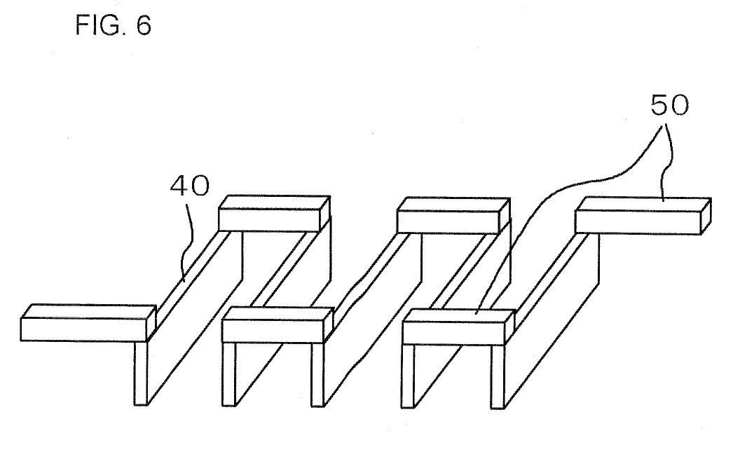

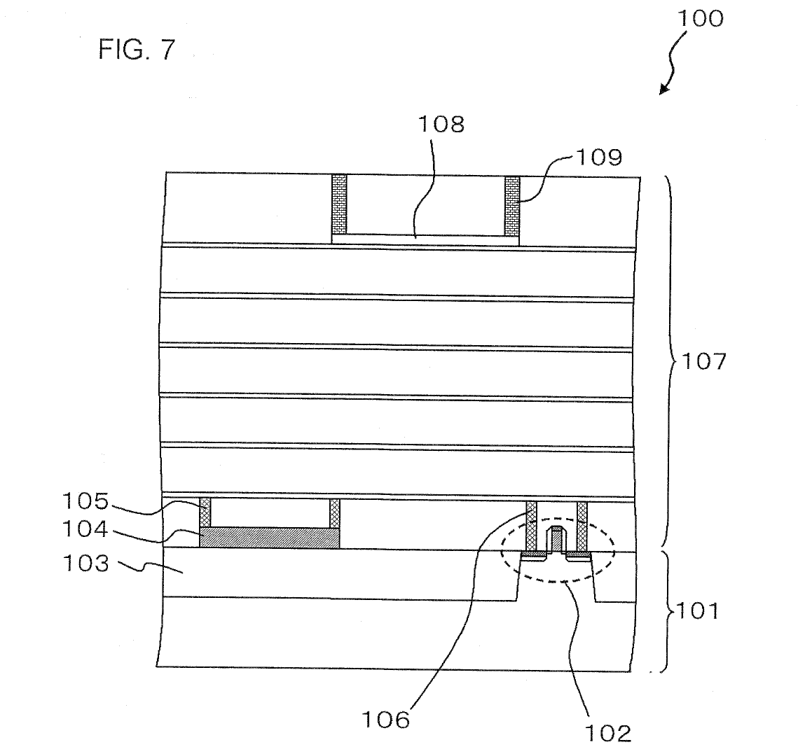

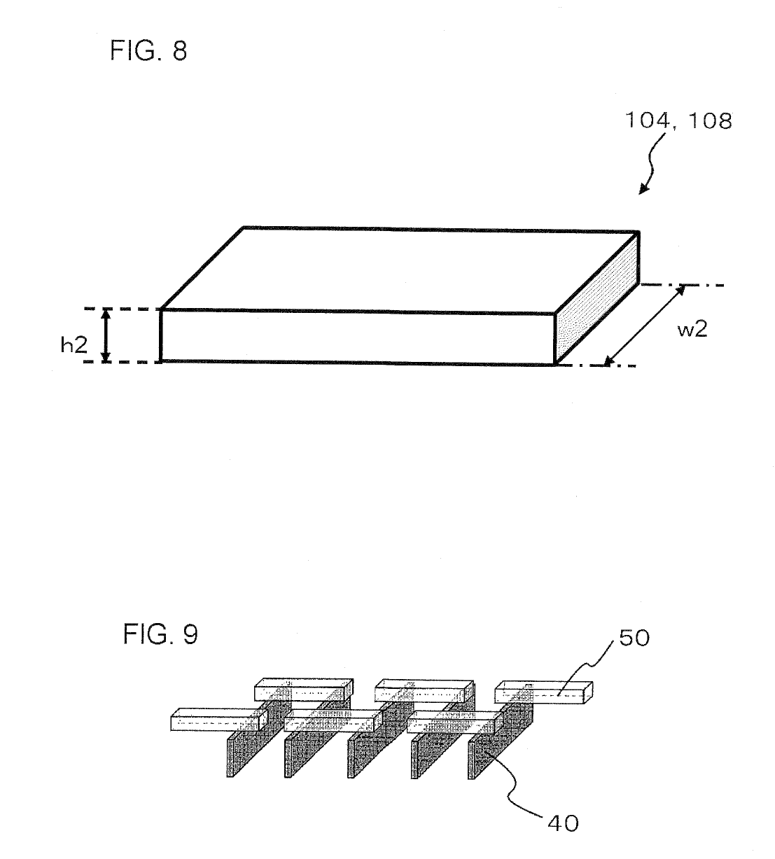

On the contrary, in a conventional semiconductor device 100 shown in FIG. 7, an additional operation of depositing a silicide block film should be included for preventing a silicidation of the polysilicon resistor 104, due to the formation of the polysilicon resistor 104. Unless such silicide block film is provided, the process for silicidizing the outer layer of the source-drain region and the outer layer of the gate electrode in the transistor 102 additionally causes unwanted silicidation of the polysilicon resistor 104. In addition, the portions of the silicide block film, which have been deposited on the portions that should have been silicidized, should be removed. Therefore, an additional etching process for such purpose should also be included. Moreover, an impurity contaminated in silicon during the etching process may cause an abnormal growth of silicide. On the contrary, according to the present embodiment, such problem can be avoided, since a deposition of a silicide block film and subsequent etching process are not required.

Further, in the conventional semiconductor device 100, a material having higher resistance should be employed for the metallic resistor 108. Therefore, the formation of the metallic resistor 108 can not be carried out at the same time as forming the via plugs or the like, causing a requirement for additional process operations. In addition, since the metallic resistor 108 is provided in the uppermost layer of the interconnect layer 107, a further formation of the interconnects is required, in addition to the existing interconnects. Therefore, this leads to a problem of requiring a larger area for devices. On the contrary, according to the present embodiment, a requirement for further forming the interconnects in the uppermost layer can be avoided since the resistive element 40 is provided in the lowermost layer of the interconnect layer 60, so that a reduced dimension of the devices can be achieved.

The height of the resistive element 40 is equivalent to the height of the contact plug 30 in the present embodiment. This allows directly connecting the resistive element 40 to the interconnects 50. Actually, in the semiconductor device 1, the resistive element 40 is directly connected to the interconnects 50. Thus, an electroconducting plug for connecting the resistive element 40 to the interconnect 50 is not required. Therefore, unlike as the case of the conventional semiconductor device 100 of FIG. 7, it is not necessary to include an additional process of forming such electroconducting plug.

A surface having the largest area in the surfaces in the resistive element 40 is perpendicular to the substrate surface of the semiconductor substrate 10. This means that a lower surface of the resistive element 40 facing the semiconductor substrate 10 is a surface having relatively small area. This allows reducing a parasitic capacitance generated between the resistive element 40 and the semiconductor substrate 10.

The resistive element 40, which is composed of the material that also constitutes the contact plug 30, is adopted for micro-fabrication. This also contributes reducing the dimension for the devices.

The copper interconnect formed by a damascene process is employed as the interconnect 50. This allows providing the structure, in which the interconnects 50 are connected to only portions of the upper surface of the resistive element 40, without any difficulty.

The resistive element 40 has a sheet resistance, which is lower than a sheet resistance of the polysilicon resistor or the metallic resistor. Therefore, the resistive element 40 can be preferably applied to a circuit that requires a resistive element having a relatively small resistance. Such type of circuit typically includes, for example, an AD converter circuit.

Meanwhile, Japanese Patent Laid-Open No. 2004-40,009 discloses a resistive element, which is constituted with a first metallic interconnect and a second metallic interconnect, and a through hole for connecting these interconnects. The inside of the through hole is filled with a resistive material. However, in such conventional resistive element, a resistor component extending along a direction that is perpendicular to the substrate surface of the semiconductor substrate is mainly utilized. Hence, a large area is required for obtaining a desired resistance. On the contrary, according to the present embodiment, a resistor component that is oriented in parallel with the substrate surface is employed, so that a desired resistance can be obtained with a smaller area thereof.

### Second Embodiment

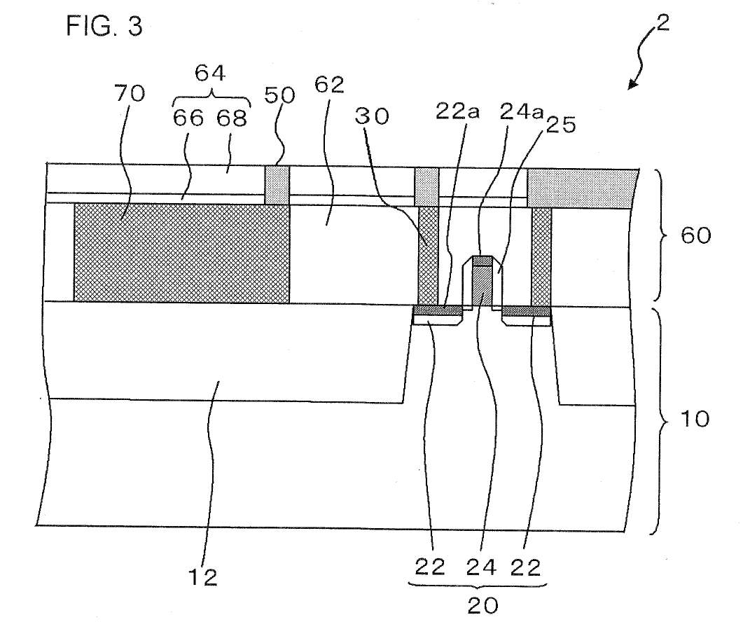

FIG. 3 is a cross-sectional view, showing second embodiment of a semiconductor device according to the present invention.

A semiconductor device 2 includes a semiconductor substrate 10, an FET 20, contact plugs 30, a plurality of capacitance electrodes 70 (specific members) and interconnects 50. Constitutions of the semiconductor substrate 10, the interconnect layer 60, the FET 20 and the contact plug 30 are similar as described in relation to FIG. 1. In addition, constitutions of the respective capacitance electrodes 70 are similar to the resistive element 40 shown in FIG. 1. Therefore, each of the capacitance electrodes 70 is provided in the layer that also includes the contact plug 30 and is composed of the material that also forms the contact plug 30.

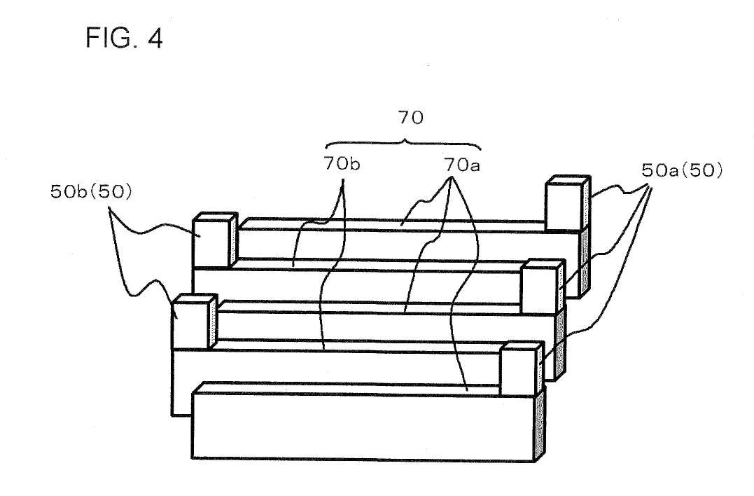

FIG. 4 is a perspective view showing the capacitance electrode 70 and the interconnects 50. As can be seen from the diagram, the capacitance electrode 70 includes capacitance electrodes 70a (first specific members) functioning as one electrode of the capacitor element and capacitance electrodes 70b functioning as the other electrode (second specific members). A plurality of first specific members 70a and a plurality of second specific members 70b are provided to be alternately disposed. The adjacent first specific member 70a and the second specific member 70b are mutually opposed, except the respective end portions. These capacitance electrodes 70a and 70b constitute an interdigital capacitor element. In addition to above, the capacitance electrode 70a or the capacitance electrode 70b does not necessarily include a plurality of electrodes, and each one of the capacitance electrodes 70a and 70b may be provided one by one to be mutually opposed.

The capacitance electrode 70a is connected to the interconnect 50a at end portion that is not opposed to the capacitance electrode 70b. The interconnect 50a is connected to an end portion that is at the same side (right side in the diagram) of a plurality of capacitance electrodes 70a. The interconnects 50a are mutually electrically connected. Similarly, the capacitance electrode 70b is connected to the interconnect 50b at end portion that is not opposed to the capacitance electrode 70a. The interconnect 50b is connected to an end portion that is at the same side (left side in the diagram) of a plurality of capacitance electrodes 70b. The interconnects 50b are mutually electrically connected The interconnect 50a and the interconnect 50b are connected to, for example, a ground and a power supply, respectively. In addition to above, in the present embodiment the plurality of interconnects 50a may be provided as one integrated interconnect. The interconnects 50b may also be provided as one integrated interconnect.

The semiconductor device 2 having such constitutions may also be manufactured in the similar manner as manufacturing the semiconductor device 1 of FIG. 1. Therefore, the capacitance electrode 70 is formed at the same time as forming the contact plug 30.

Advantageous effects obtainable by employing the configuration of the present embodiment will be described. The surface having the largest area in the surfaces in the capacitance electrode 70 is perpendicular to the substrate surface of the semiconductor substrate 10. More specifically, the side surface dimension of the capacitance electrode 70 is increased. This is advantageous in constituting an interdigital capacitor element.

Each of the capacitance electrodes 70 has an uniform thickness. Thus, by disposing a plurality of capacitance electrodes 70 to form a parallel pattern, a constant distance between such electrodes can also be obtained. Thus, the capacitance electrode 70 is adopted for constituting the capacitor element.

Meanwhile, Japanese Patent Laid-Open No. H10-65,101 (1998) discloses a capacitor element composed of a capacitance electrode, which is formed at the same time as forming the contact electrode. However, in such conventional capacitor element, an interconnect is connected to the entire upper surface of the capacitance electrode. Hence, in consideration of the distance between the interconnects and an allowance for misalignment of the interconnects, it is difficult to have a reduced distance between the capacitance electrodes.

On the contrary, since the interconnects 50 are connected to only portions of the upper surface of capacitance electrode 70 according to the present embodiment, the capacitance electrodes 70 can be arranged to be mutually opposed, without the interconnects 50 being mutually opposed. Therefore, a reduced distance between the capacitance electrodes 70 can be achieved. Further, the adjacent capacitance electrodes 70 are mutually opposed, except the respective end portions, and are connected to the interconnects 50 at end portions that are not mutually opposed. This allows obtaining the structure, in which the interconnect 50 is not opposed to the capacitance electrode 70. According to such structure, the distance between the capacitance electrodes 70 can be still further reduced. Other advantageous effects of the present embodiment are similar to that obtained in first embodiment.

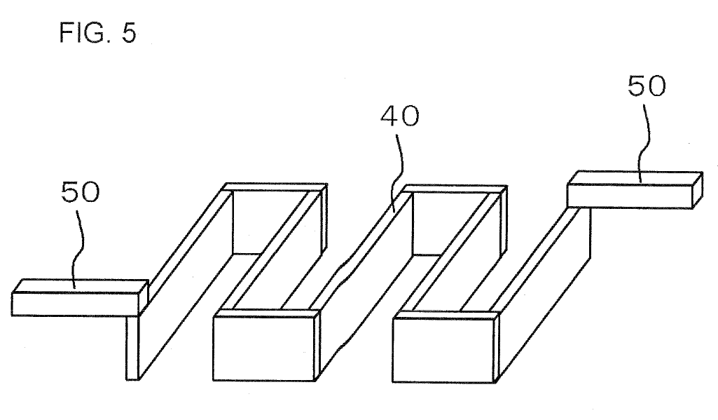

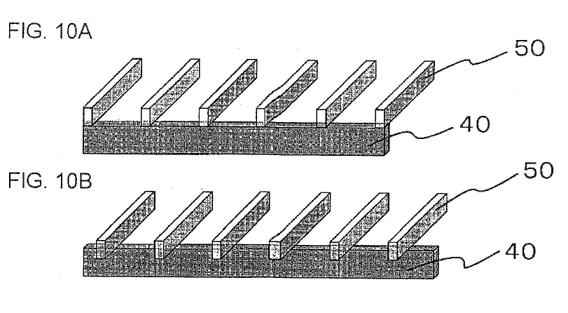

It is intended that the semiconductor device and the method of manufacturing the semiconductor device according to the present invention is not limited to the above-described embodiments, and various modifications thereof are available. For example, various configurations may be considered for the resistive element, in addition to the element shown in FIG. 2. An example thereof is shown in FIG. 5, FIG. 6, FIG. 9 and FIGS. 10A and 10B. In FIG. 5, the resistive element 40 is provided in a meander form in a surface that is in parallel with the substrate surface of the semiconductor substrate. The resistive element 40 thereof is also connected to the interconnect 50 at both ends in the elongation direction.

In FIG. 6, a plurality of resistive elements 40 are provided to form a mutually-opposing arrangement. These resistive elements 40 are mutually connected in series by interconnects 50 to form a resistive element. In FIG. 9 a plurality of resistive elements 40 elongate along a direction in parallel with the substrate surface of said semiconductor substrate 10, and are connected to the interconnects 50 at except both ends in the elongation direction. In addition, show in FIG. 10B, the resistive element 40 elongates along a direction in parallel with the substrate surface of the semiconductor substrate, and is projected from said interconnect by connected to the interconnects 50 at a portion except both ends in the elongating direction, and the interconnects 50 are projected from the resistive element 40 by connected to the resistive element 40 at a portion except both ends in the elongating direction. In addition, show in FIGS. 10A and 10B, one resistive elements 40 may be connected to a plurality of interconnects 50. According to the structure of FIG. 5, FIG. 6, FIG. 9 and FIGS. 10A and 10B, a larger resistance can be obtained, even if a sufficient space for disposing the resistive elements along a straight line is not assured.

In addition, the exemplary implementations for providing a connecting of the interconnects to the end portion of the specific member has been illustrated in the above-described embodiments. However, it is sufficient that the interconnect is connected to a portion of the upper surface of the specific member, and may be connected to a section thereof except the end portion.

It is apparent that the present invention is not limited to the above embodiment, and may be modified and changed without departing from the scope and spirit of the invention.

What is claimed is:

1. A semiconductor device, comprising:
a semiconductor substrate having a transistor formed therein;
a contact plug, provided on said semiconductor substrate and connected to said transistor;
a specific member constituting a passive element, said specific member being provided in a layer on said semiconductor substrate that also includes said contact plug, and being composed of a material that also composes said contact plug; and
an interconnect connected to a portion of an upper surface of said specific member.

2. The semiconductor device as set forth in claim 1, wherein said passive element is a resistive element.

3. The semiconductor device as set forth in claim 2, wherein said specific member elongates along a direction in parallel with the substrate surface of said semiconductor substrate, and is connected to said interconnect at both ends along the elongating direction.

4. The semiconductor device as set forth in claim 2, wherein said specific member elongates along a direction in parallel with the substrate surface of said semiconductor substrate, and is projected from said interconnect by connected to said interconnect at a portion except both ends in the elongating direction,
and/or wherein said interconnect is projected from said specific member by connected to said specific member at a portion except both ends in the elongating direction.

5. The semiconductor device as set forth in claim 2, wherein the shortest electric current path in said specific member is in parallel with the substrate surface of said semiconductor substrate.

6. The semiconductor device as set forth in claim 2, wherein said specific member is provided in a meander form in a surface that is in parallel with the substrate surface of said semiconductor substrate.

7. The semiconductor device as set forth in claim 2, further comprising a plurality of said specific members, wherein said plurality of said specific members are mutually connected in series by said interconnect to form one of said resistive element.

8. The semiconductor device as set forth in claim 6, wherein said plurality of said specific members are disposed to be mutually opposed.

9. The semiconductor device as set forth in claim 4 further comprising a plurality of said specific members, wherein said plurality of said specific members are mutually connected in series by said interconnect to form one of said resistive element.

10. The semiconductor device as set forth in claim 4, wherein said plurality of said specific members are disposed to be mutually opposed.

11. The semiconductor device as set forth in claim 3, wherein one said specific member is connected to more than three said interconnects.

12. The semiconductor device as set forth in claim 11, wherein said specific member elongates along a direction in parallel with the substrate surface of said semiconductor substrate, and is projected from said interconnect by connected to said interconnect at a portion except both ends in the elongating direction,
and/or wherein said interconnect is projected from said specific member by connected to said specific member at a portion except both ends in the elongating direction.

13. The semiconductor device as set forth in claim 1, wherein said passive element is a capacitor element.

14. The semiconductor device as set forth in claim 13, further comprising a plurality of said specific members, wherein said plurality of said specific members include a first specific member functioning as an electrode of said capacitor element and a second specific member functioning as the other electrode of said capacitor element.

15. The semiconductor device as set forth in claim 14, wherein each of said specific members elongates along a direction in parallel with the substrate surface of said semiconductor substrate, and is connected to said interconnect at both ends along the elongating direction.

16. The semiconductor device as set forth in claim 14, wherein a plurality of said first specific members and a plurality of said second specific members are provided to be alternately disposed.

17. The semiconductor device as set forth in claim 14, wherein said first specific member and said second specific member are mutually opposed, except the respective end portions.

18. The semiconductor device as set forth in claim 1, wherein a height of said specific member is equivalent to a height of said contact plug.

19. The semiconductor device as set forth in claim 1, wherein said specific member is provided on an element isolation region of said semiconductor substrate.

20. The semiconductor device as set forth in claim 1, wherein said specific member is directly connected to said interconnect.

21. The semiconductor device as set forth in claim 1, wherein said specific member has a constant width.

22. The semiconductor device as set forth in claim 1, wherein a surface having the largest area in the surfaces of said specific member is perpendicular to the substrate surface of said semiconductor substrate.

23. The semiconductor device as set forth in claim 1, wherein said interconnect is a copper interconnect.

24. A method of manufacturing a semiconductor device, comprising:
forming a transistor in a semiconductor substrate;
forming a contact plug on said semiconductor substrate so as to be connected to said transistor;
forming a specific member constituting a passive element on said semiconductor substrate; and
forming an interconnect so as to be connected to a portion of an upper surface of said specific member,
wherein said contact plug is formed simultaneously with forming said specific member.

25. The method of manufacturing the semiconductor device as set forth in claim 24, wherein said interconnect is formed by a damascene process.
